(19) United States
(12) Patent Application Publication
(10) Pub. No.: US 2026/0239595 A1
(43) Pub. Date: Aug. 13, 2026

(54) HYBRID CHANNEL BEOL TFT FOR DRAM APPLICATIONS

(71) Applicant: Taiwan Semiconductor Manufacturing Company, Ltd., Hsinchu (TW)

(72) Inventors: Wai-Kit Lee, Tuen Mun (HK); Katherine H. Chiang, New Taipei City (TW); Chih-Yu Chang, New Taipei City (TW); Cheng-Yi Wu, Taichung City (TW)

(21) Appl. No.: 19/052,608

(22) Filed: Feb. 13, 2025

(51) Int. Cl. H10B 12/00

(52) U.S. Cl. CPC H10B 12/00

(57) ABSTRACT

An integrated chip includes a write transistor arranged over an upper surface of a substrate, and a read transistor arranged over the write transistor. The write transistor includes a first channel region vertically extending in a first direction perpendicular to the upper surface of the substrate, a first gate region vertically extending in the first direction and arranged along the first channel region, and a first source/drain region and a second source/drain region respectively in contact with a top portion and a bottom portion of the first channel region. The read transistor includes a second channel region extending in a second direction in parallel with the upper surface and a second gate region extending in a third direction in parallel with the upper surface and perpendicular to the second direction. The second gate region is arranged under the second channel region and over the first channel region.

### BACKGROUND

As technology progresses, the minimum size of the circuit element that can be manufactured in an integrated chip (IC) continues to decrease. Hence, there is an ever-increasing demand for increasing the number of circuit elements in an IC of the same or smaller size. One way to increase the circuit element density in an IC is to make circuit elements in multiple layers of the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated chip (IC) including a dynamic random-access memory (DRAM) cell according to some embodiments of the present disclosure.

FIG. 2 illustrates a circuit diagram of the DRAM cell as shown in FIG. 1 according to some embodiments of the present disclosure.

FIG. 3 illustrates a cross-sectional view of multiple (e.g., two) DRAM cells as shown in FIG. 1 electrically coupled to each other according to some embodiments of the present disclosure.

FIG. 4 illustrates a cross-sectional view of multiple (e.g., two) alternative DRAM cells electrically coupled to each other according to other embodiments of the present disclosure.

FIG. 5 illustrates a top view of multiple DRAM cells as shown in FIG. 3 electrically coupled to each other according to some embodiments of the present disclosure.

FIG. 6 illustrates a top view of multiple alternative DRAM cells electrically coupled to each other according to other embodiments of the present disclosure.

FIGS. 7A-7C, 8A, 9A, 10A, 11A, 12A-12B, 13A-13B, 14A-14B, 15A, 16A, 17A-17B, 18A, 19A, 20A, 21A, 22A, 23A-23B, 24A, 25A, 26A and 27A-27B illustrate DRAM cells for explaining exemplary steps of making one or more DRAM cells according to some embodiments of the present disclosure.

FIG. 28 illustrates an exemplary flow diagram of a method of manufacturing a DRAM cell in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In the present disclosure, layers/patterns/structures being formed of substantially the same material means that the layers/patterns/structures are formed of the same material or the layers/patterns/structures are originally formed of the same material but can have impurities having the same or different types with the same or different concentrations doped later in order to implement a semiconductor device. Such a description should be recognizable to one of ordinary skill in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A conventional Dynamic Random-Access Memory (DRAM) Memory cell typically adopts a 1T1C configuration. This DRAM cell typically has a source of an access transistor (e.g., a planar transistor) connected to a capacitor, and utilizes the capacitor to store data. However, the electric quantity of the capacitor of this DRAM cell is consumed during reading, and the capacitor of this DRAM cell leaks, thus the electric charge in the capacitor needs to be periodically refreshed, and the power consumption is larger. Another challenge of this DRAM cell is that both the planar access transistor and the capacitor are difficult to scale. Stacking layers of this DRAM cell to increase the density is hindered by the height of the capacitor.

An alternative DRAM cell typically adopts two planar transistors and zero capacitor (2T0C) configuration, stores charges with a gate of one of the two planar transistors, and changes transistor transconductance of that transistor to store information. Multiple layers of transistors of the alternative DRAM cell in the 2T0C configuration (i.e., a dual transistor setup) can be easily implemented since there are no capacitors. However, this dual transistor setup of the alternative DRAM cell may meet challenges to further reduce the size thereof and suppress the short channel effect (e.g., low leakage) due to large sizes of the conventional planar transistors in the same layer of the alternative DRAM cell.

The present disclosure provides various embodiments of an integrated chip (IC) including a DRAM cell in a 2T0C configuration. In some embodiments, the integrated chip includes a vertical write transistor arranged over an upper surface of a substrate, and a planar read transistor arranged over the vertical write transistor. The vertical write transistor includes a first channel region vertically extending in a first direction (Z-direction) that is perpendicular to the upper surface of the substrate, a first gate region vertically extending in the first direction and arranged along the first channel region, and a first source/drain region and a second source/drain region respectively in contact with a top portion and a bottom portion of the first channel region. The planar read transistor includes a second channel region laterally extending in a second direction (X-direction) that is in parallel with the upper surface of the substrate, and a second gate region laterally extending in the second direction. The second gate region of the planar read transistor is arranged under the second channel region of the planar read transistor and over the first channel region of the vertical write transistor. In some embodiments, the second gate region of the planar read transistor is in contact with the first channel region of the vertical write transistor, and the first source/drain region of the vertical write transistor is part of the second gate region of the planar read transistor.

As such, in the DRAM cell in 2T0C configuration of the present disclosure, the vertical write transistor that has a vertical channel is arranged directly below the planar read transistor that has a planar channel, thereby advantageously leading to a reduced DRAM cell size and an increased DRAM cell density in a DRAM cell array. In some embodiments, the vertical channel of the vertical write transistor is formed by a disposal spacer process and thus can advantageously be made very thin. In some embodiments, the vertical channel of the vertical write transistor can be made in gate-all-around (GAA) configuration, thereby advantageously leading to better gate control and further suppressed short channel effect.

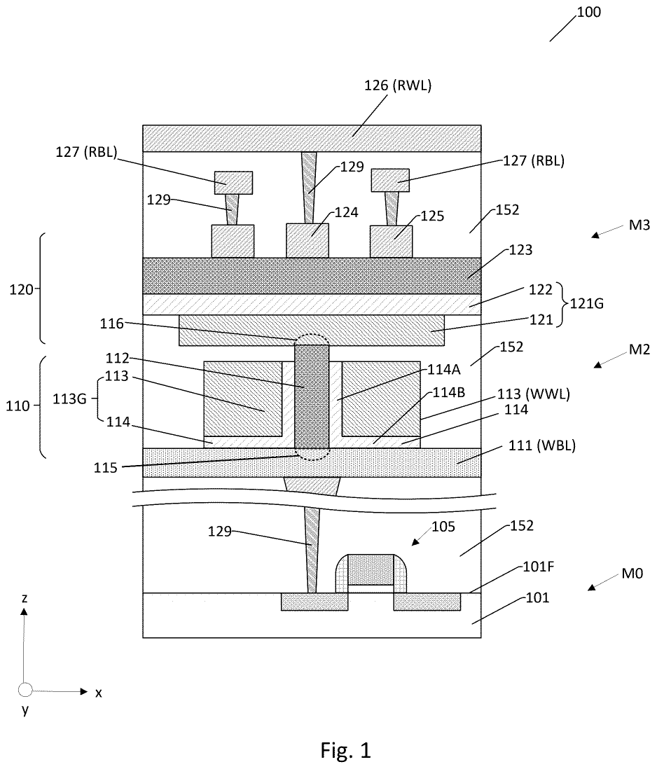

FIG. 1 illustrates a cross-sectional view of an integrated chip (IC) that includes a dynamic random-access memory (DRAM) cell 100 according to some embodiments of the present disclosure. It should be understood that the DRAM cell 100 is simplified for illustrative purpose, and thus the arrangement of components of the DRAM cell 100 can be configured in various other manners, and the DRAM cell 100 can include any of other components while remaining within the scope of the present disclosure. In the present disclosure, not every layer of a cell or a layout is depicted in the drawings. One of ordinary skill in the art should understand that the cell or the layout can include more layers to implement functionality of the cell and these layers are omitted merely for convenience of description.

ICs can be fabricated on semiconductor wafers (such as silicon wafers) by semiconductor manufacturing processes. These processes can be divided into Front-End-Of-Line (FEOL) processing and Back-End-Of-Line (BEOL) processing. In the context of the present disclosure, FEOL processing refers to steps and processes that relate to the formation of transistors in or directly on a semiconductor substrate, while BEOL processing refers to steps and processes that relate to the formation of interconnection (e.g., elements for interconnecting the transistors formed in FEOL processing) and passivation. In the context of the present disclosure, BEOL processing may refer to formation of an interconnection metal layer M1 and other interconnection metal layers (such as M2, M3, M4, . . . ) above M1 over the semiconductor substrate.

Certain FEOL processes may require a relatively high temperature. For example, the annealing performed after certain types of doping processes may reach 1000° C. or even higher temperatures. The high temperatures may prevent the use of some materials in the FEOL processing. In contrast, a lower processing temperature may be sufficient for common manufacturing steps employed in the BEOL processing (such as deposition), so the BEOL processing may have a lower temperature budget than the FEOL processing. The lower temperature budget may advantageously enable the usage of materials that are unavailable to the FEOL processing because of the temperature constraint.

Different types of memories can be fabricated with specialized semiconductor manufacturing processes. Two types of memory are common, e.g., static random-access memory (SRAM) and dynamic random-access memory (DRAM). A unit SRAM cell may use multiple (such as six, eight, or ten) transistors, while a unit DRAM cell may advantageously use as few elements as one transistor (e.g., an access transistor) and one capacitor (the “1T1C” configuration), or two transistors (e.g., an access transistor and a storage transistor) and zero capacitors (the “2T0C” configuration), for example.

The DRAM transistors in 2T0C configuration can be formed with FEOL processing, however these transistors formed with FEOL processing may compete with the transistors of logic circuitry for the same semiconductor substrate area. Hence, it would be advantageous to provide DRAM transistors in 2T0C configuration in upper interconnection metal layers, such as M1, M2, M3 . . . Mn (e.g., n=20), over the semiconductor substrate with steps and processes available in BEOL processing, thereby advantageously providing unit DRAM cells with reduced power consumption and footprints.

As shown in FIG. 1, in some embodiments, a DRAM cell 100 of an integrated chip (IC) includes a write transistor 110 that is arranged over an upper surface 101F of a semiconductor substrate 101, and a read transistor 120 that is arranged over the write transistor 110. In some embodiments, both of the write transistor 110 and the read transistor 120 are thin-film transistors (TFTs). For example, the write transistor 110 can be formed in an interconnection metal layer M2 over the semiconductor substrate 101, and the read transistor 120 can be formed directly above the write transistor 110 in an interconnection metal layer M3. In addition, the write transistor 110 and the read transistor 120 can advantageously be formed with steps and processes available in BEOL processing.

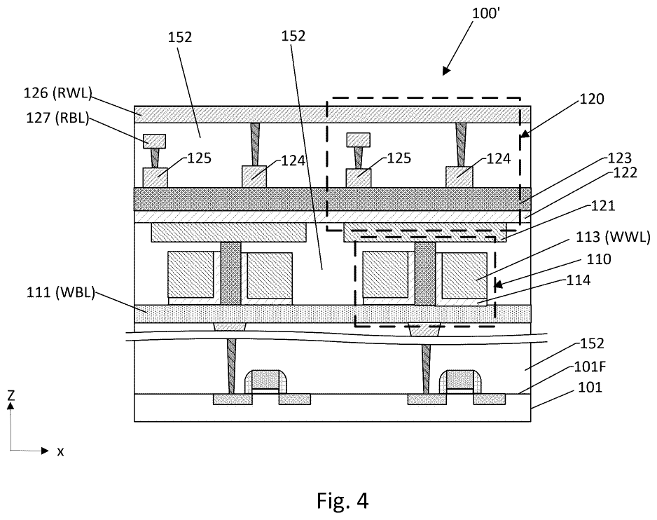

In some embodiments, the write transistor 110 includes a first channel region 112, a first gate region 113, a first gate dielectric 114, a first source/drain region 115, and a second source/drain region 116. In some embodiments, the read transistor 120 includes a second gate region 121, a second gate dielectric 122, a second channel region 123, a source region 124, and first and second drain regions 125. In other embodiments, as shown in FIG. 4, the read transistor 120 includes a source region 124 and a drain region 125. In some embodiments, a first conductive line 111 that may function as a write bit line (WBL) 111 of the write transistor 110 is arranged directly under and in contact with the write transistor 110. Source/drain region(s) may refer to a source or a drain, individually or collectively dependent upon the context. In some embodiments, the source and drain regions 124, 125 may each be referred to as source/drain regions.

In some embodiments, the DRAM cell 100 includes interlayer dielectric (ILD) layers 152, which can be used to provide electrical isolation among some conductive components, reduce parasitic capacitance, and provide mechanical protection. In some embodiments, the ILD layers 152 can be made of a low-k dielectric material, e.g., silicon dioxide (SiO2), organ silicate glasses (OSGs), fluorinated silicate glass (FSG), spin-on dielectrics (SOD), and the like.

In some embodiments, the first channel region 112 of the write transistor 110 vertically extends in a first direction (Z-direction) perpendicular to the upper surface 101F of the semiconductor substrate 101. In some embodiments, the first channel region 112 of the write transistor 110 includes an oxide semiconductor material including at least one of indium zinc oxide, indium tin oxide, indium oxide, gallium oxide, indium gallium zinc oxide, zinc oxide, aluminum-doped zinc oxide, indium tungsten oxide, and titanium oxide. In other embodiments, the first channel region 112 of the write transistor 110 includes other III-V materials or combinations (e.g., alloys or stacked layers) thereof.

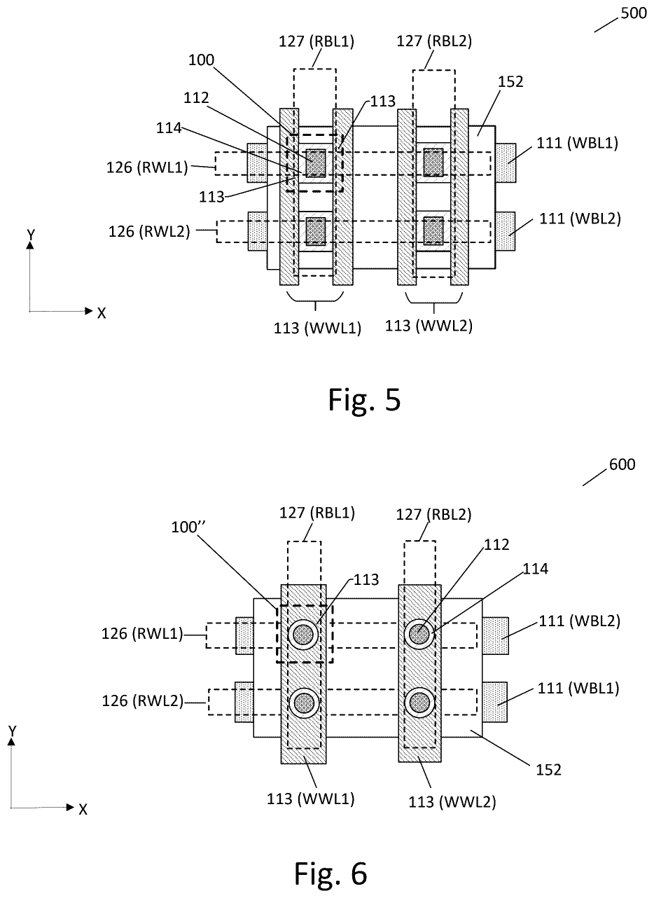

In some embodiments, the first gate region 113 of the write transistor 110 vertically extends in the first direction (Z-direction) and is arranged along the first channel region 112 in the first direction (Z-direction). In some embodiments, the first gate region 113 includes a conductive material that includes at least one of titanium nitride, tungsten, or molybdenum. In some embodiments, referring to FIGS. 1 and 5, a write word line (WWL) 113 laterally extends in a third direction (Y-direction) that is perpendicular to the second direction (X-direction), and the first gate region 113 also laterally extends in the third direction (Y-direction). In some embodiments, the first gate region 113 is part of the write word line (WWL) 113.

In some embodiments, the first gate dielectric 114 of the write transistor 110 is L-shaped, and includes a vertical portion 114A and a lateral portion 114B. The vertical portion 114A vertically extends in the first direction (Z-direction) and is arranged laterally between the first channel region 112 and the first gate region 113, and the lateral portion 114B is arranged beneath the first gate region 113 and vertically between the first gate region 113 and the first conductive line 111 to separate them. In some embodiments, the first gate dielectric 114 includes a high dielectric constant (high-k) dielectric material that includes hafnium oxide (HfO₂), zirconium oxide (ZrO₂), aluminum oxide (Al₂O₃), lanthanum oxide (La₂O₃), tantalum oxide (Ta₂O₅), and the like.

In some embodiments, the first gate region 113 and the first gate dielectric 114 of the write transistor 110 combinedly form a first gate structure 113G that partially (as shown in FIG. 5) or completely (as shown in FIG. 6) wraps around a portion of the first channel region 112 beneath a top portion of the first channel region 112.

In some embodiments, a first source/drain region 115 of the write transistor 110 is in contact with a bottom portion of the first channel region 112, and a second source/drain region 116 of the write transistor 110 is in contact with a top portion of the first channel region 112. In some embodiments, the first source/drain region 115 of the write transistor 110 is in contact with the first conductive line 111 that extends in a second direction (X-direction) in parallel with the upper surface 101F of the semiconductor substrate 101, and is part of the first conductive line 111. In some embodiments, the second source/drain region 116 of the write transistor 110 is in contact with the second gate region 121 of the read transistor 120, and is part of the second gate region 121 of the read transistor 120.

In some embodiments, the first channel region 112 of the write transistor 110 protrudes from the top surfaces of the first gate region 113 and the first gate dielectric 114 that are substantially flush with each other. In some embodiments, the first gate region 113 of the write transistor 110 and the second gate region 121 of the read transistor 120 are electrically separated from each other by a portion of an ILD layer 152.

In some embodiments, the second gate region 121 of the read transistor 120 laterally extends in the third direction (Y-direction) that is in parallel with the upper surface 101F of the semiconductor substrate 101, the second channel region 123 of the read transistor 120 laterally extends in the second direction (X-direction) that is in parallel with the upper surface 101F of the semiconductor substrate 101, and the second gate dielectric 122 of the read transistor 120 laterally extends in the second direction (X-direction) and is arranged vertically between the second gate region 121 and the second channel region 123 to separate them from each other.

In some embodiments, the second gate region 121 and the second gate dielectric 122 of the read transistor 120 combinedly form a second gate structure 121G. In some embodiments, the second gate region 121 includes a conductive material that includes at least one of titanium nitride, tungsten, or molybdenum. In some embodiments, the second gate dielectric 122 includes a high dielectric constant (high-k) dielectric material that includes hafnium oxide (HfO₂), zirconium oxide (ZrO₂), aluminum oxide (Al₂O₃), lanthanum oxide (La₂O₃), tantalum oxide (Ta₂O₅), and the like. In some embodiments, the second channel region 123 includes an oxide semiconductor material including at least one of indium zinc oxide, indium tin oxide, indium oxide, gallium oxide, indium gallium zinc oxide, zinc oxide, aluminum-doped zinc oxide, indium tungsten oxide, and titanium oxide. In other embodiments, the second channel region 123 of the read transistor 120 includes other III-V materials or combinations (e.g., alloys or stacked layers) thereof.

In some embodiments, the source region 124 of the read transistor 120 is arranged on the second channel region 123, and the first and the second drain regions 125 of the read transistor 120 are laterally arranged on opposite sides of the source region 124 along the second channel region 123. In some embodiments, the source region 124 of the read transistor 120 is in electrical contact with a read word line (RWL) 126 through a via 129, and the first and the second drain regions 125 of the read transistor 120 are respectively in electrical contact with read bit lines (RBLs) 127 through vias 129. The read word line (RWL) 126 laterally extends in the second direction (X-direction), and the read bit lines (RBLs) 127 laterally extend in the third direction (Y-direction).

In some embodiments, the IC further includes a lower transistor 105 arranged on the semiconductor substrate 101. The lower transistor 105 comprises a gate dielectric layer on the semiconductor substrate 101, a gate electrode on the gate dielectric layer, and a pair of source/drain regions in the semiconductor substrate 101 and on opposing sides of the gate electrode. The lower transistor 105 may be processed with FEOL processing. Further, the lower transistor 105 may, for example, be a metal-oxide semiconductor field-effect transistor (MOSFET), a fin field-effect transistor (finFET), or the like.

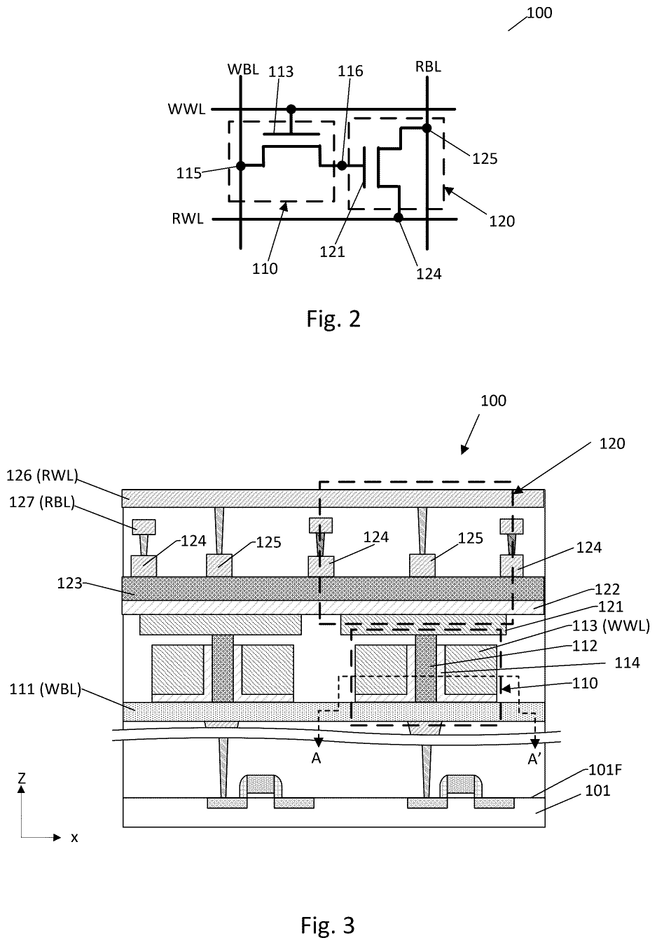

FIG. 2 illustrates a circuit diagram of the DRAM cell 100 in 2T0C configuration as shown in FIG. 1 according to some embodiments of the present disclosure, which can be used to store and access data. The DRAM cell 100 as shown in FIG. 2 includes a write transistor 110 and a read transistor 120 coupled to each other. Referring to FIGS. 1 and 2, the write transistor 110 includes a vertical first channel region 112, a first gate region 113 coupled to a write word line (WWL), a first source/drain region 115 coupled to a write bit line (WBL) 111, and a second source/drain region 116. The read transistor 120 includes a planar second channel region 123, a second gate region 121 coupled to the second source/drain region 116 of the write transistor 110, a source region 124 coupled to a read word line (RWL) 126, and a drain region 125 coupled to a read bit line (RBL) 127. Referring to FIG. 1, as aforementioned, the write transistor 110 is arranged over an upper surface 101F of a semiconductor substrate 101, and the read transistor 120 is arranged directly over the write transistor 110. As such, the DRAM cell 100 with hybrid (i.e., vertical and planar) channels can advantageously bring about reduced DRAM cell size and thus increased DRAM cell density in a DRAM cell array, and can advantageously be processed with BEOL processing.

FIG. 3 illustrates a cross-sectional view of multiple (e.g., two) DRAM cells 100 as shown in FIG. 1 that are electrically coupled according to some embodiments of the present disclosure. As shown in FIG. 3, a unit DRAM cell 100 includes a write transistor 110 with a vertical first channel region 112 arranged over a semiconductor substrate 101, and a read transistor 120 with a planar second channel region 123 arranged directly over the write transistor 110. In some embodiments, the read transistor 120 of the unit DRAM cell 100 includes one source region 124 and two drain regions 125 that are all arranged along the planar second channel region 123, and the two drain regions 125 are arranged laterally on opposite sides of the source region 124.

FIG. 4 illustrates a cross-sectional view of multiple (e.g., two) alternative DRAM cells 100′ that are electrically coupled according to other embodiments of the present disclosure. As shown in FIG. 4, similar to the unit DRAM cell 100 in FIG. 3, an alternative unit DRAM cell 100′ also includes a write transistor 110 with a vertical first channel region 112 arranged over a semiconductor substrate 101, and a read transistor 120 with a planar second channel region 123 arranged directly over the write transistor 110. In some embodiments, different from the unit DRAM cell 100 in FIG. 3, the read transistor 120 of the alternative unit DRAM cell 100′ as shown in FIG. 4 includes one source region 124 and one drain region 125 arranged along the planar second channel region 123.

FIG. 5 illustrates a top view 500 of multiple (e.g., two) DRAM cells 100 electrically coupled to each other, seen through lines A-A′ in FIG. 3, according to some embodiments of the present disclosure. Referring to FIGS. 1, 3 and 5, write bit lines 111 (e.g., WBL1 and WBL2) extend in parallel with each other in the second direction (X-direction) (one in contact with the first source/drain region 115 of the write transistor 110 in FIG. 1), write word lines 113 (e.g., WWL1 and WWL2) extend in parallel with each other in the third direction (Y-direction) (one in contact with the first gate region 113 of the write transistor 110 in FIG. 1), read word lines 126 (e.g., RWL1 and RWL2) extend in parallel with each other in the second direction (X-direction) (one coupled to the source region 124 of the read transistor 120 in FIG. 1), read bit lines 127 (e.g., RBL1 and RBL2) extend in parallel with each other in the third direction (Y-direction) (coupled to two drain regions 125 of the read transistor 120 in FIG. 1). In some embodiments, the bit lines 111, the write word lines 113, the read word lines 126, and the read bit lines 127 are arranged in different interconnection metal layers over the interconnection metal layer M0.

Referring to FIG. 5, in an embodiment, a first gate region 113 of a write transistor 110 partially wraps around a first channel region 112 of the write transistor 110 substantially along the second direction (e.g., X-direction) with a first gate dielectric 114 arranged between the first gate region 113 and the first gate dielectric 114.

FIG. 6 illustrates a top view 600 of multiple (e.g., two) alternative DRAM cells 100″ electrically coupled to each other according to another embodiment of the present disclosure. The embodiment as shown in FIG. 6 is similar to the embodiment as shown in FIG. 5, except that the first gate region 113 of the write transistor 110 completely wraps around the first channel region 112 of the write transistor 110, in a gate-all-around (GAA) configuration, with a first gate dielectric 114 arranged therebetween.

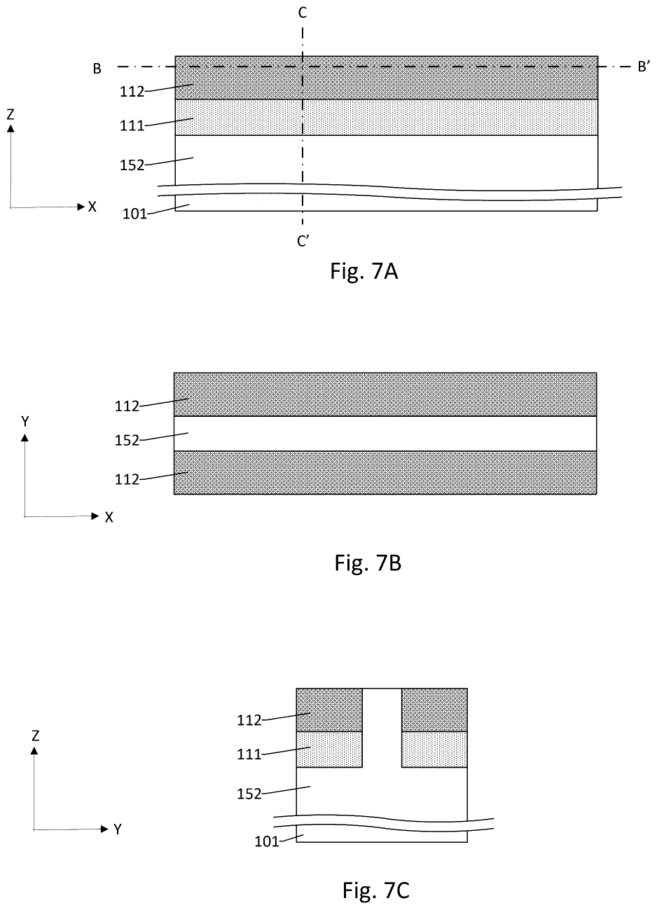

FIGS. 7A-27B illustrate DRAM cells at various stages for explaining exemplary steps for making DRAM cells (e.g., 100 as shown in FIG. 1 and 3 or 100′ as shown in FIG. 4) according to some embodiments of the present disclosure. Unless otherwise indicated, among FIGS. 7A-27B, figures whose numbers end with an “A” indicate a cross-sectional view cut along X-Z directions, figures whose numbers end with a “B” indicate a top view cut along X-Y directions, and figures whose numbers end with a “C” indicate another cross-sectional view cut along Y-Z directions.

Refer to FIG. 7A (a cross-sectional view of DRAM cells), FIG. 7B (a top view cut along line B-B′ of FIG. 7A), and FIG. 7C (another cross-sectional view cut along line C-C′ of FIG. 7A), an ILD layer 152 is formed (e.g., by deposition), at least two first conductive lines or layers 111 are formed (e.g., by photolithography, etching, and deposition) on the ILD layer 152, and at least two first channel layers 112 are formed (e.g., by deposition) on the first conductive lines 111 (which will be formed into two or more write bit lines 111).

In some embodiments, the first channel layers 112 are made of an oxide semiconductor material including at least one of indium zinc oxide, indium tin oxide, indium oxide, gallium oxide, indium gallium zinc oxide, zinc oxide, aluminum-doped zinc oxide, indium tungsten oxide, and titanium oxide.

In some embodiments, adjacent first conductive lines 111 and adjacent first channel layers 112 laterally extend in parallel with each other along the second direction (X-direction), and are laterally separated from each other by a portion of the ILD layer 152 in the third direction (Y-direction).

In some embodiments, also referring to FIG. 1, the ILD layer 152 is formed over an upper surface 101F of a semiconductor substrate 101 in an interconnection metal layer, such as M1, and other structures of the DRAM cells are formed in other interconnection metal layers, such as M2, M3, M4 . . . Mn (e.g., n=20) over M1, and thus the DRAM cells 100 as shown in FIG. 1 can advantageously be manufactured by BEOL processes.

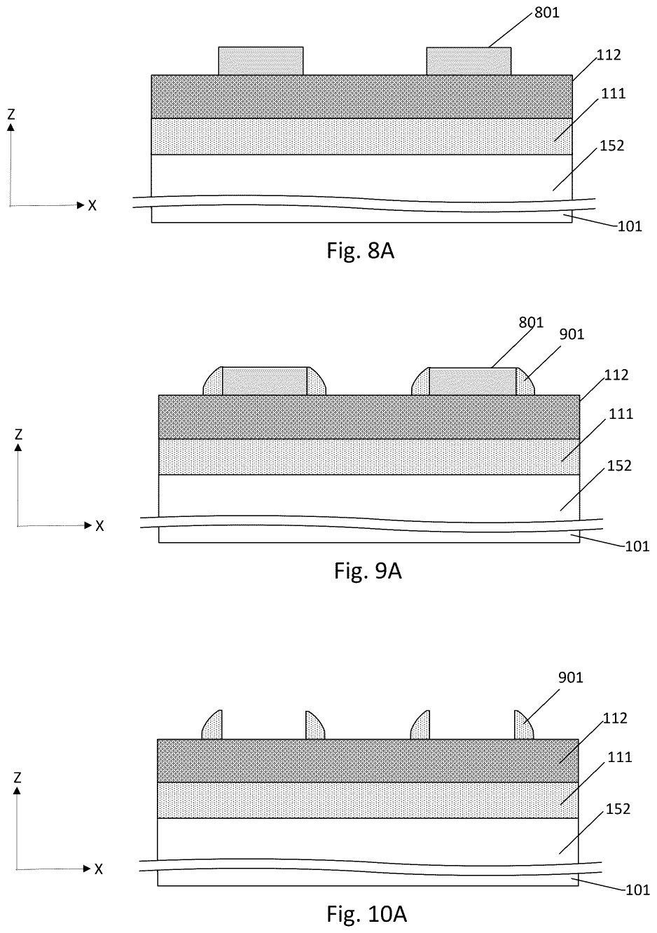

FIGS. 8A through 12B illustrate processes of forming the first channel regions 112 over the first conductive lines 111. Referring to FIG. 8A, dummy (or sacrificial) conductive materials 801 made of such as copper, aluminum, or polysilicon are deposited on the top surface of the first channel layer 112. Referring to FIG. 9A, spacers 901 of a solid material made of such as SN, SiO₂ are formed on sidewalls of the dummy conductive materials 801 by deposition and etching (such as wet-etching) processes.

Referring to FIG. 10A, the dummy conductive materials 801 are selectively removed from the top surface of the first channel layer 112 by using a selective solvent. For example, ammonium persulfate solution or ferric chloride (FeCl₃) can be used for removing copper material; phosphoric acid (H₃PO₄) with a small amount of nitric acid (HNO₃), acetic acid can be used for removing aluminum material; and potassium hydroxide (KOH) or tetramethylammonium hydroxide (TMAH) can be used for removing polysilicon material. As such, the spacers 901 are remained on the top surface of the first channel layer 112, and can be used as hard masks (HMs) for forming the first channel regions 112 of the write transistor 110 of a DRAM cell 100 in FIG. 1.

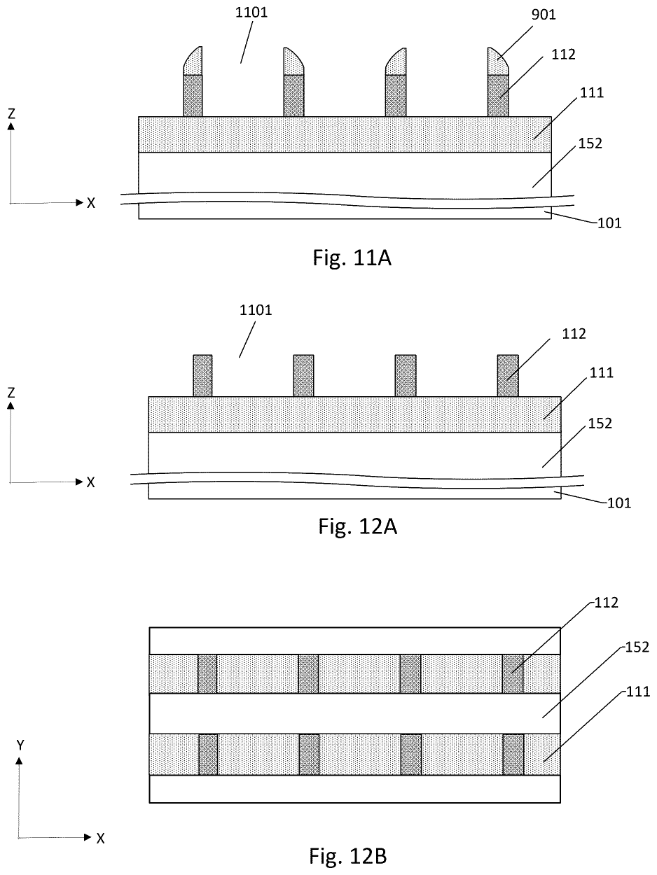

Referring to FIGS. 11A and 12A-12B, the first channel layer 112 is etched by using the spacers 901 as hard masks, trenches 1101 are thus formed, and then the spacers 901 are removed by e.g., chemical-mechanical planarization (CMP) or etching, thereby forming multiple first channel regions 112 on the top surface of the first conductive line 111.

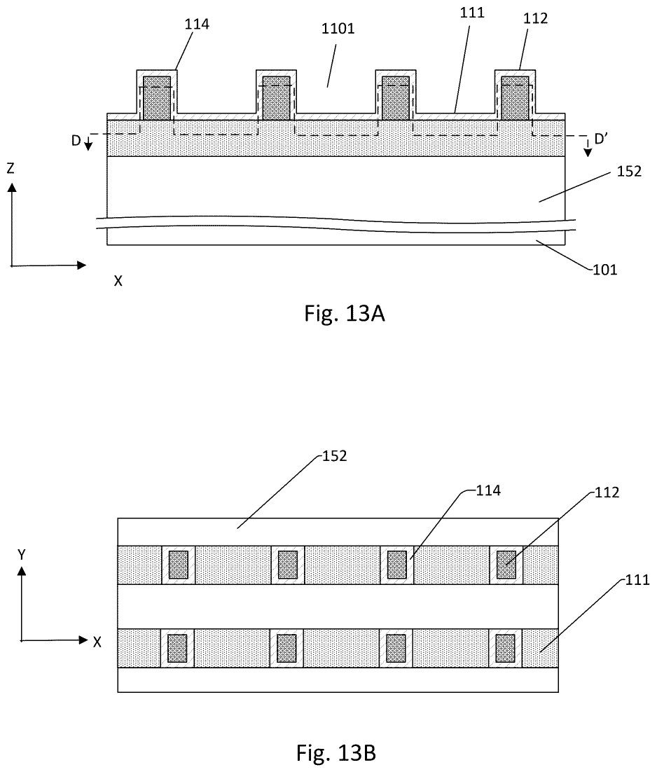

Referring to FIG. 13A, a first gate dielectric layer 114 (which will be used to form the first gate dielectrics 114 as shown in FIG. 1) is formed as a thin layer by conformal deposition over the first channel regions 112 and the first conductive line 111. In some embodiments, the first gate dielectric layer 114 is formed by an atomic layer deposition (ALD) process to conformally cover the first channel regions 112 and the first conductive line 111. FIG. 13B is a top view of the DRAM cells cut along a line D-D′ in FIG. 13A.

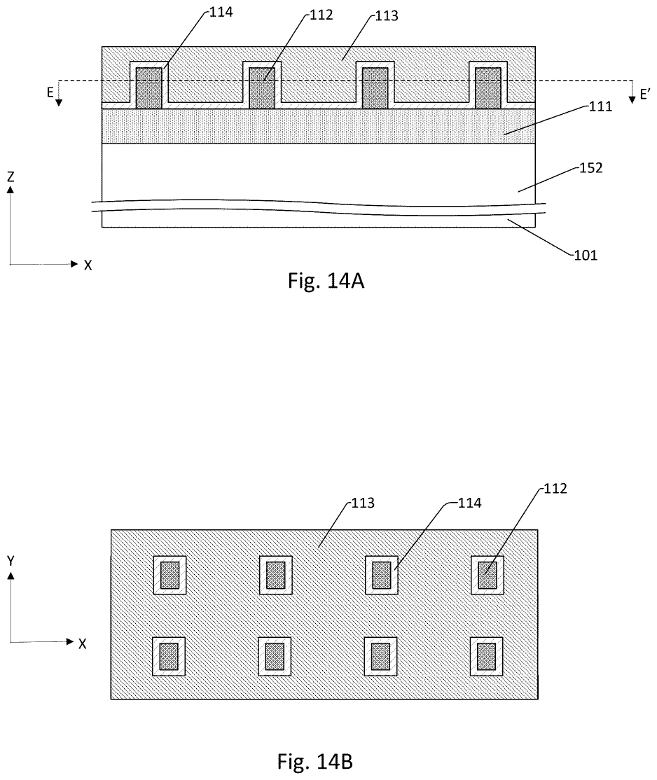

Referring to FIG. 14A, a material of the first gate region 113 is deposited into the trenches 1101 as shown in FIG. 11. FIG. 14B is a top view of the DRAM cells 100 viewed through cutline E-E′ in FIG. 14A. Referring to FIG. 15A, trenches 1501 are formed into the material of the first gate region 113 e.g., by employing photolithography and etching processes, and thus multiple first gate structures 113G each including a first gate region 113 and a first gate dielectric 114 are formed. A first gate structures 113G includes a first gate region 113 and a first gate dielectric 114.

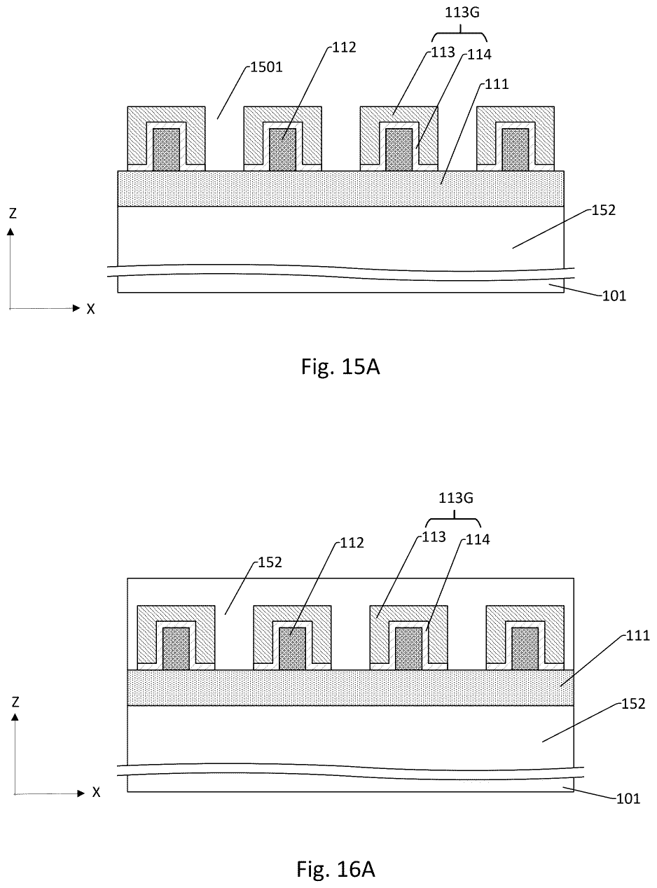

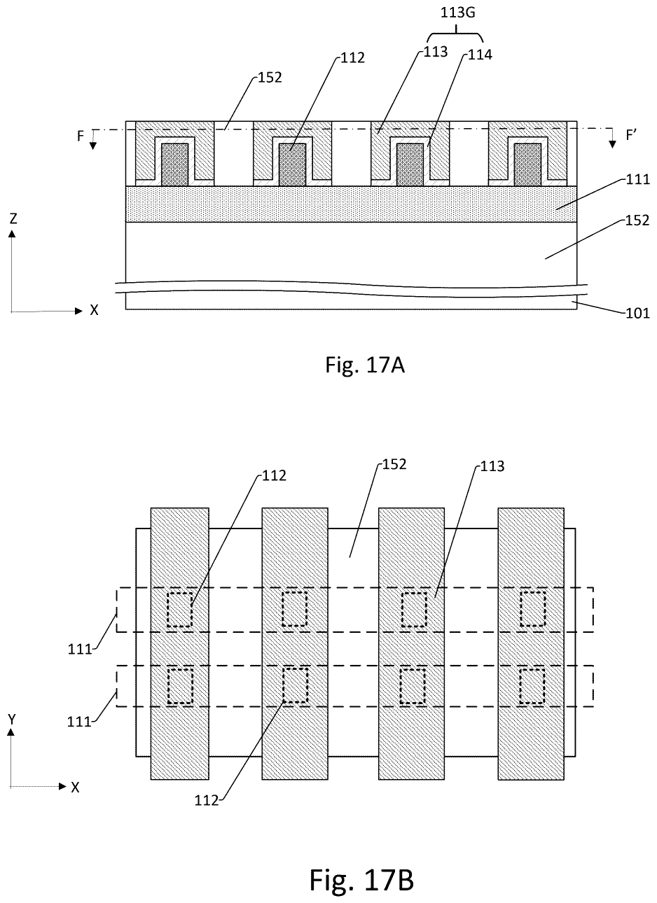

Referring to FIG. 16A, a material of the ILD layer 152 is deposited into the trenches 1501 as shown in FIG. 15A, adjacent first gate structures 113G are separated from one another by a portion of the ILD layer 152. Referring to FIG. 17A, a CMP process is performed to remove excessive dielectric material of the ILD layer 152 to expose upper surfaces of the first gate regions 113. FIG. 17B is a top view of the DRAM cells viewed through cutline F-F′ in FIG. 17A.

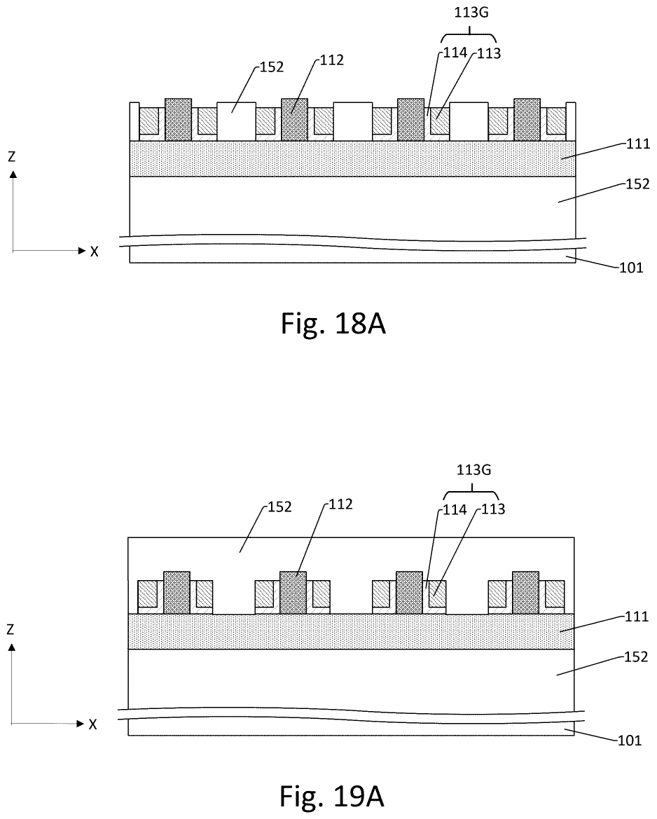

Referring to FIG. 18A, a wet etching process is performed to selectively remove portions of the first gate regions 113 and the first gate dielectrics 114 from the top of the DRAM cell by a solvent or etchant, which can selectively remove the first gate regions 113 and the first gate dielectrics 114 faster than removing the first channel regions 112. As such, the first channel regions 112 protrude from the first gate regions 113 and the first gate dielectrics 114 that are substantially flush with each other.

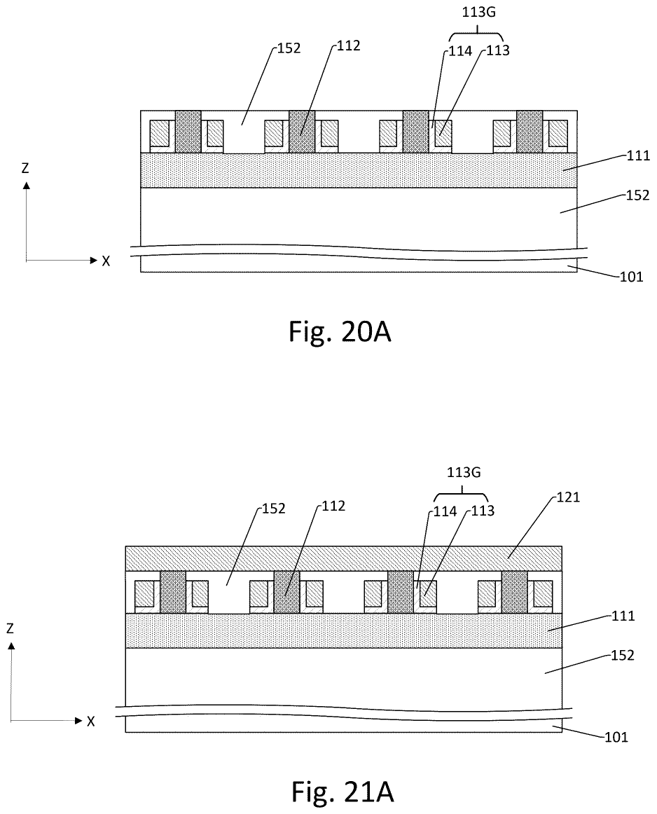

Referring to FIG. 19A, a material of the ILD layer 152 is deposited to cover the first channel regions 112, the first gate regions 113, and the first gate dielectrics 114. Referring to FIG. 20A, a CMP process is performed to remove excessive material of the ILD layer 152 to expose upper surfaces of the first channel regions 112, and also planarize the upper surfaces of the DRAM cells.

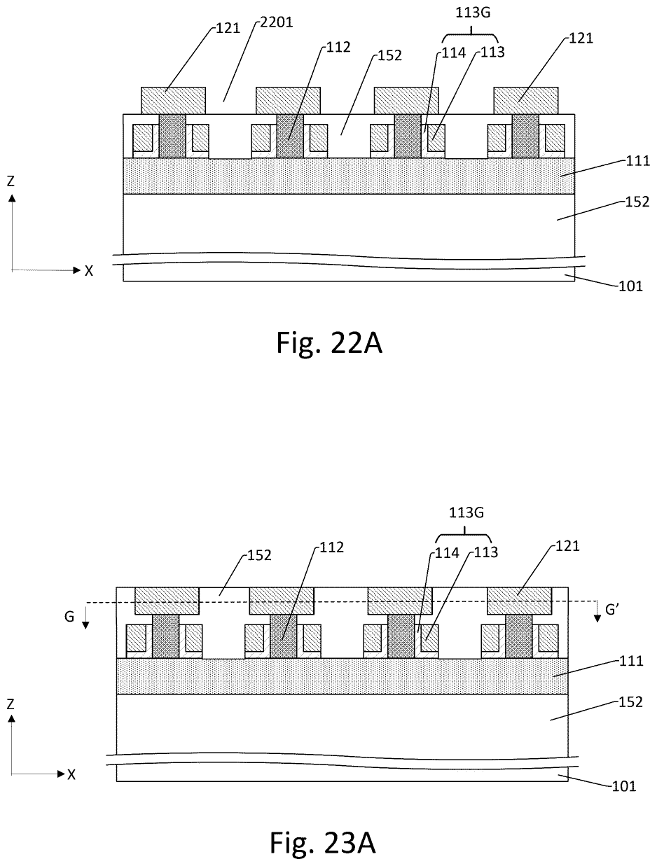

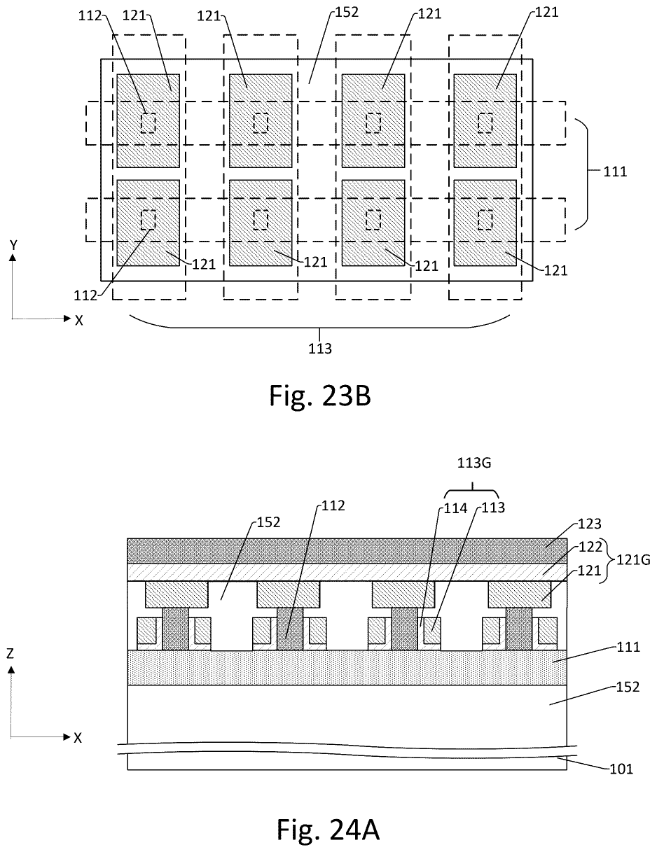

Referring to FIG. 21A, a conductive material of the second gate regions 121 are deposited directly over and in contact with the first channel regions 112 by a deposition process. Referring to FIG. 22A, the second gate regions 121 are formed by photolithography and etching processes, and trenches 2201 are also formed between adjacent second gate regions 121. Referring to FIG. 23A, the material of the ILD layer 152 is deposited into the trenches 2201 in FIG. 22A, and excessive material of the ILD layer 152 is removed by a CMP process to expose upper surfaces of the second gate regions 121. FIG. 23B illustrates a top view of the DRAM cells viewed through cutline G-G′ in FIG. 23A.

Referring to FIG. 24A, a second gate dielectric 122 is formed directly over and in contact with the second gate regions 121 by deposition, and a second channel region 123 is formed directly over and in contact with the second gate dielectric 122 by deposition. In some embodiments, the second gate dielectric 122 and the second gate regions 121 combinedly form second gate structures 121G.

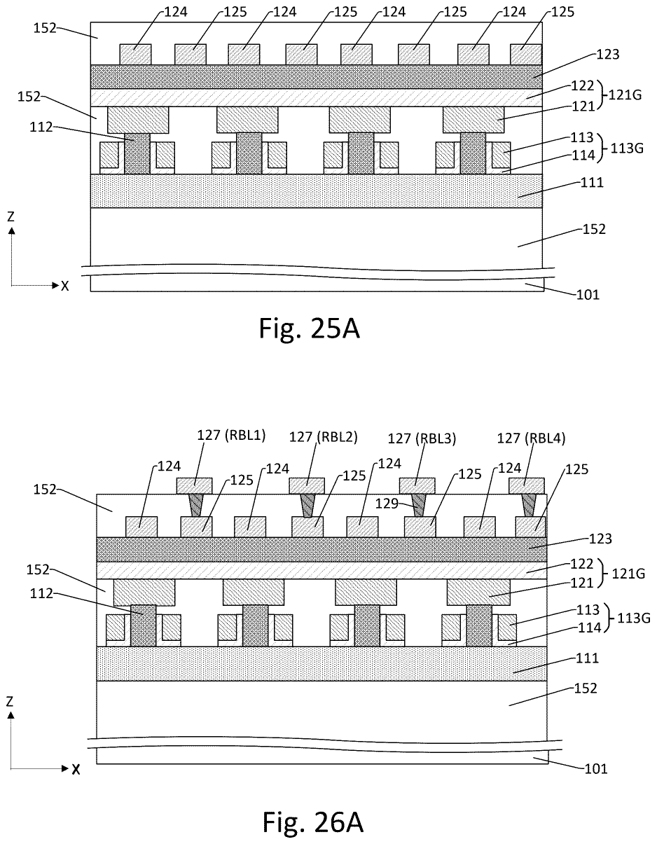

Referring to FIG. 25A, source regions 124 and drain regions 125 are formed directly over and along the second channel region 123 (e.g., by deposition, photolithography, and etching), and the material of the ILD layer 152 is deposited on the source regions 124 and the drain regions 125. The source regions 124 and the drain regions 125 are isolated from each other by a portion of the ILD layer 152. Referring to FIG. 26A, read bit lines 127 (e.g., RBL1, RBL2, RBL3 and RBL4) are formed over and coupled to the drain regions 125 through vias 129 that are formed in the ILD layer 152.

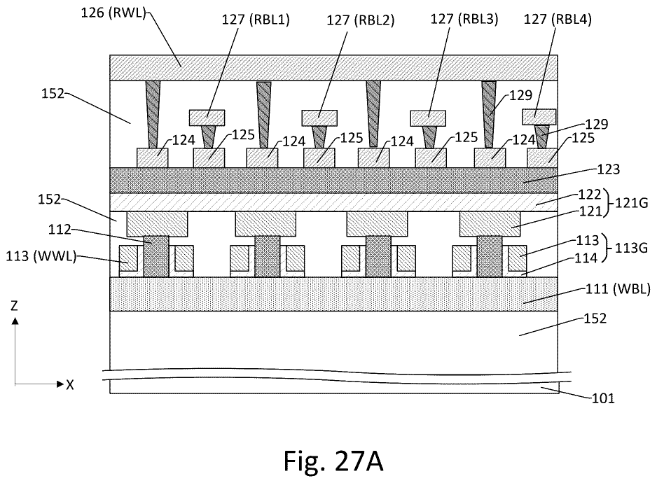

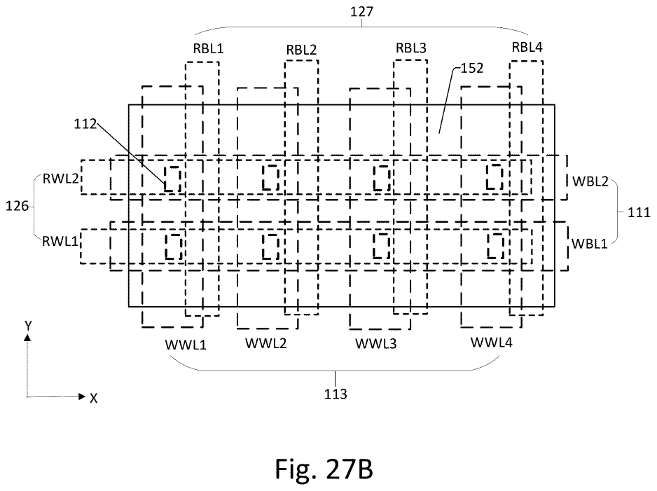

Referring to FIG. 27A (which is a cross-sectional view of the final structures of the DRAM cells), one or more read word lines 126 (e.g., RWL) are formed over and coupled to the source regions 124 through vias 129. The read word lines 126, the read bit lines 127, and the vias 129 are isolated from each other by a portion of the ILD layer 152. Also referring to FIG. 27B (which is a schematic top view of the final structure shown in FIG. 27A), in some embodiments, the DRAM cells (e.g., as shown in FIG. 4) are coupled to write bit lines 111 (e.g., WBL1 and WBL2) extending in the second direction (X-direction), to write word lines 113 (e.g., WWL1, WWL2, WWL3 and WWL4) extending in the third direction (Y-direction), to read word lines 126 (e.g., RWL1 and RWL2) extending in the second direction (X-direction), and to read bit lines 127 (e.g., RBL1, RBL2, RBL3 and RBL4) extending in the third direction (Y-direction).

The exemplary process flow of the present disclosure may enable the formation of transistor structures of the DRAM cells without using doping or implantation steps. This may help reduce the maximum temperature in the process flow, because the annealing after doping and implantation may require higher temperatures. In some embodiments, the maximum temperature in such a process flow is about 400° C. This temperature range may enable the use of oxide semiconductor materials such as IGZO.

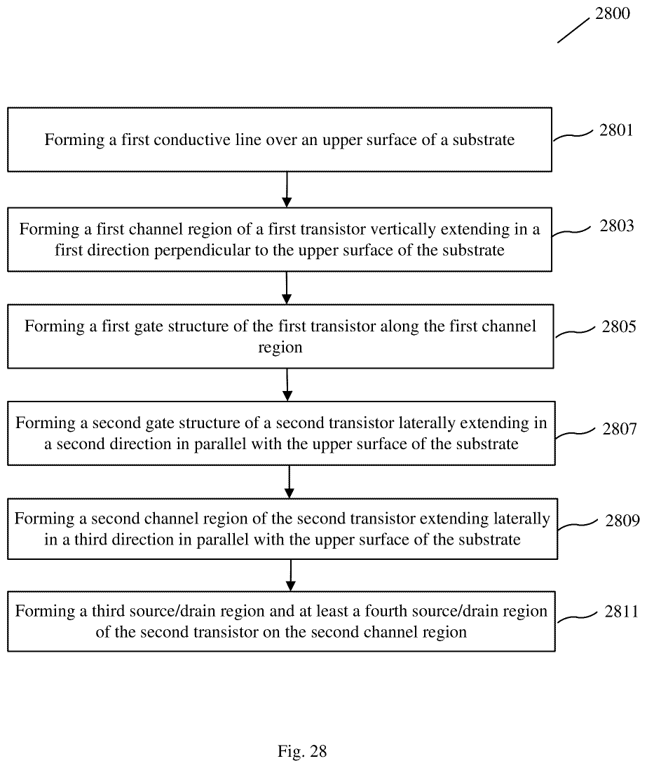

FIG. 28 illustrates an exemplary flow diagram of a method 2800 of manufacturing one or more DRAM cells 100 as shown in FIG. 1 in accordance with some embodiments of the present disclosure. It should be noted that the method 2800 is merely an example, and is not intended to limit the present disclosure. Accordingly, it is understood that the order of operations of the method 2800 of FIG. 28 can be changed, additional operations can be provided before, during, and after the method 2800 of FIG. 28, and other operations may be described briefly herein.

A DRAM cell 100 as shown in FIG. 1 fabricated by the method 2800 of FIG. 28 may include a write transistor 110 and a read transistor 120 among other things. In some embodiments, the write transistor 110 includes a vertical first channel region 112, a first gate region 113, a first gate dielectric 114, a first source/drain region 115, and a second source/drain region 116, and the read transistor 120 includes a second gate region 121, a second gate dielectric 122, and a planar second channel region 123. In some embodiments, the read transistor 120 includes a source region 124, and a first and a second drain regions 125. In other embodiments, the read transistor 120 includes a source region 124, and a drain region 125. In some embodiments, a first conductive line 111 that may function as a write bit line (WBL) 111 of the write transistor 110 is arranged directly under and in contact with the write transistor 110. In some embodiments, the first source/drain region 115 is formed by a part of the first conductive line 111 that is arranged directly under and in contact with the first channel region 112. In some embodiments, the second source/drain 116 region is formed by a part of the second gate region 121 that is arranged directly above and in contact with the first channel region 112.

Referring to FIGS. 1, 7A-7C and 28, the method 2800 starts with operation 2801 of forming a first metal line 111 over and in parallel with an upper surface 101F of a semiconductor substrate 101. In some embodiments, one or more first conductive lines 111 are formed (e.g., by photolithography, etching and deposition) on the ILD layer 152 and are arranged extending in a second direction (X-direction). For example, the ILD layer 152 is formed over the semiconductor substrate 101, e.g., in an interconnection metal layer M1, and other components or structures of the DRAM cell 100 are formed in interconnection metal layer such as M2, M3, M4 . . . Mn (e.g., n=20) over M1, and thus the structures can advantageously be manufactured by BEOL processes.

Next, referring to FIGS. 1, 7A-12B, and 28, the method 2800 proceeds to operation 2803 of forming multiple first channel regions 112 extending vertically in a first direction (Z-direction) that is perpendicular to the upper surface 101F of the semiconductor substrate 101. Refer to FIGS. 7A-7C, as aforementioned, one or more first channel layers 112 are formed (e.g., by photolithography, etching, and deposition) on a first conductive layer 111 (which will finally be formed into two or more write bit lines 111). Referring to FIGS. 8A-10A, as aforementioned, spacers 901 of a solid material (such as SN, SiO₂) are formed the top surface of the first channel layer 112. Referring to FIGS. 11A-12A, as aforementioned, the one or more first channel regions 112 are formed by using the spacers 901 as hard masks (HMs), and various processes such as photolithography, etching, deposition, and/or CMP can be used in forming the one or more first channel regions 112.

Next, referring to FIGS. 1, 13A-17B and 28, the method 2800 proceeds to operation 2805 of forming a first gate structure 113G of the write transistor 110 along the first channel region 112, and the first gate structure 113G including a first gate region 113 and a first gate dielectric 114. Referring to FIG. 13A, as aforementioned, the first gate dielectric layer 114 is formed as a thin layer by deposition (e.g., ALD) to conformally cover the first channel regions 112 and the first conductive line 111. Referring to FIG. 14A, as aforementioned, a material of the first gate region 113 is deposited into the trenches (e.g., as shown in FIG. 11), thereby covering the first gate dielectric layer 114. Referring to FIG. 15A, as aforementioned, trenches 1501 are formed into the material of the first gate region 113 by employing photolithography and etching processes. Referring to FIG. 16A, as aforementioned, a material of the ILD layer 152 is deposited into the trenches 1501, and thus multiple first gate structures 113G are formed, in which one of the first gate structures 113G including a first gate region 113 and a first gate dielectric 114 is separated from adjacent another first gate structure 113G by a portion of the ILD layer 152. Referring to FIG. 17A, as aforementioned, excessive parts of the ILD layer 152 are removed e.g., by a CMP process to expose the top surfaces of the first gate regions 113.

Next, referring to FIGS. 1, 21A-24A and 28, the method 2800 proceeds to operation 2807 of forming a second gate structure 121G (as shown in FIG. 24A) of a read transistor 120 laterally extending in a third direction (Y-direction) in parallel with the upper surface 101F of the semiconductor substrate 101 (FIG. 1). The second gate structure 121G includes a second gate region 121 arranged directly over a top portion of the first channel region 112 and a second gate dielectric 122 arranged directly over the second gate region 121. Referring to FIG. 21A-24A, as aforementioned, a conductive layer of the second gate regions 121 are deposited directly over and in contact with the first channel regions 112. Referring to FIG. 22A, as aforementioned, the second gate regions 121 are formed by photolithography and etching processes, and trenches 2201 are also formed between adjacent second gate regions 121. Referring to FIG. 23A, as aforementioned, the material of the ILD layer 152 is deposited into the trenches 2201, and excessive material of the ILD layer 152 is removed by a CMP process to expose the upper surfaces of the second gate regions 121. Referring to FIG. 24A, as aforementioned, the second gate dielectric 122 is deposited directly over and in contact with the second gate regions 121.

Next, referring to FIGS. 24A and 28 the method 2800 proceeds to operation 2809 of forming a second channel region 123 of the read transistor 120 extending laterally in the second direction (X-direction) and directly over the second gate structure 121G. Referring to FIG. 24A, as aforementioned, the second channel region 123 is deposited directly over and in contact with the second gate dielectric 122.

Next, referring to FIGS. 25A and 28, the method 2800 proceeds to operation 2811 of forming a source region 124 and at least one drain region 125 of the read transistor 120 on the planar second channel region 123. In some embodiments, the read transistor 120 of each DRAM cell 100 includes one source region 124 and one drain region 125. In other embodiments, the read transistor 120 of each DRAM cell 100 includes one source region 124 and two drain regions 125. Referring to FIG. 25A, in some embodiments, the source regions 124 and the drain regions 125 are deposited directly over and along the second channel region 123, and the source regions 124 and the drain regions 125 are isolated from each other by a portion of the ILD layer 152.

In some embodiments, referring to FIG. 26A, the read bit lines (RBLs) 127 are formed over and coupled to the drain regions 125 through vias 129. In some embodiments, referring to FIG. 27A, the read word lines (RWLs) 126 are formed over and coupled to the source regions 124 through vias 129. The read word lines 126, the read bit lines 127, and the vias 129 are separated or isolated from each other by a portion of the ILD layer 152.

As such, a DRAM cell in 2T0C configuration of the present disclosure includes a vertical write transistor with a vertical channel arranged directly below a planar read transistor with a planar channel, and thus this hybrid channel structure employed by the DRAM cell advantageously leads to a reduced DRAM cell size and an increased DRAM cell density. In addition, the maximum temperature in the process flow in a relative low temperature range (e.g., about 400 degrees C), which enables the use of oxide semiconductor materials such as IGZO, the write transistor and the read transistor of the present disclosure can advantageously be formed with steps and processes available in BEOL process.

In one aspect of the present disclosure, an integrated chip is disclosed. The integrated chip includes a write transistor arranged over an upper surface of a substrate, and a read transistor arranged over the write transistor. The write transistor includes a first channel region vertically extending in a first direction that is perpendicular to the upper surface of the substrate; a first gate region vertically extending in the first direction and arranged along the first channel region; and a first source/drain region and a second source/drain region respectively in contact with a top portion and a bottom portion of the first channel region. The read transistor includes a second channel region laterally extending in a second direction that is in parallel with the upper surface of the substrate; and a second gate region laterally extending in a third direction that is in parallel with the upper surface of the substrate and perpendicular to the second direction. The second gate region is arranged under the second channel region and over the first channel region of the write transistor.

In another aspect of the present disclosure, a method for forming an integrated chip is disclosed. The method includes forming a first transistor over an upper surface of a substrate, and forming a second transistor over the first transistor. Forming the first transistor includes forming a first conductive line over the substrate, in which a first source/drain region of the first transistor is part of the first conductive line; forming a first channel region vertically extending in a first direction that is perpendicular to the upper surface of the substrate; and forming a first gate region vertically extending in the first direction and along the first channel region. Forming the second transistor includes forming a second gate region over the first channel region and laterally extending in a second direction that is in parallel with the upper surface of the substrate, in which a second source/drain region of the first transistor is part of the second gate region; forming a second channel region over the second gate region and laterally extending in a third direction that is in parallel with the upper surface of the substrate and perpendicular to the second direction; and forming a third source/drain region and a fourth source/drain region on the second channel region.

In yet another aspect of the present disclosure, a method of manufacturing an integrated chip is disclosed. The method includes forming a first conductive line over an upper surface of a substrate; depositing a first channel layer over the first conductive line; patterning the first channel layer to form a first channel region of a first transistor vertically extending in a first direction perpendicular to the upper surface of the substrate; forming a first gate structure of the first transistor along the first channel region, and including a first gate region and a first gate dielectric, in which the first transistor comprises a first source/drain region and a second source/drain region; forming a second gate structure of a second transistor laterally extending in a second direction in parallel with the upper surface of the substrate, and including a second gate region directly over a top portion of the first channel region and a second gate dielectric region directly over the second gate region; depositing a second channel region of the second transistor extending laterally in a third direction in parallel with the upper surface of the substrate and perpendicular to the second direction and directly over the second gate structure; and forming a third source/drain region and at least a fourth source/drain region of the second transistor on the second channel region.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a write transistor arranged over an upper surface of a substrate and comprising:
a first channel region vertically extending in a first direction that is perpendicular to the upper surface of the substrate;
a first gate region vertically extending in the first direction and arranged along the first channel region; and
a first source/drain region and a second source/drain region respectively in contact with a bottom portion and a top portion of the first channel region; and
a read transistor arranged over the write transistor and comprising:
a second channel region laterally extending in a second direction that is in parallel with the upper surface of the substrate; and
a second gate region laterally extending in a third direction that is in parallel with the upper surface of the substrate and perpendicular to the second direction, wherein the second gate region is arranged under the second channel region and over the first channel region of the write transistor.

2. The integrated chip of claim 1, wherein the second gate region of the read transistor is in contact with the first channel region of the write transistor, and wherein the second source/drain region of the write transistor is part of the second gate region of the read transistor.

3. The integrated chip of claim 1, further comprising a write bit line laterally extending in the second direction, and arranged under and in contact with the first channel region of the write transistor, wherein the first source/drain region of the write transistor is part of the write bit line.

4. The integrated chip of claim 1, further comprising a write word line laterally extending in the third direction, wherein the first gate region laterally extends in the third direction and is part of the write word line.

5. The integrated chip of claim 1, wherein the read transistor further comprises:
a source region arranged on the second channel region and in electrical contact with a read word line; and
a drain region arranged on the second channel region and in electrical contact with a read bit line.

6. The integrated chip of claim 5, wherein the read transistor further comprises:
a second drain region arranged on the second channel region and in electrical contact with the read bit line, the drain region and the second drain region being laterally arranged on opposite sides of the source region along the second channel region.

7. The integrated chip of claim 1, wherein at least one of the first channel region and the second channel region comprises at least one of indium zinc oxide, indium tin oxide, indium oxide, gallium oxide, indium gallium zinc oxide, zinc oxide, aluminum-doped zinc oxide, indium tungsten oxide, and titanium oxide.

8. The integrated chip of claim 1, wherein at least one of the first gate region and the second gate region comprises at least one of titanium nitride, tungsten, or molybdenum.

9. A method for forming an integrated chip, comprising:
forming a first transistor over an upper surface of a substrate, wherein forming the first transistor comprises:
forming a first conductive line over the substrate, wherein a first source/drain region of the first transistor is part of the first conductive line;
forming a first channel region vertically extending in a first direction that is perpendicular to the upper surface of the substrate; and
forming a first gate region vertically extending in the first direction and along the first channel region; and
forming a second transistor over the first transistor, wherein forming the second transistor comprises:
forming a second gate region over the first channel region and laterally extending in a second direction that is in parallel with the upper surface of the substrate, wherein a second source/drain region of the first transistor is part of the second gate region;
forming a second channel region over the second gate region and laterally extending in a third direction that is in parallel with the upper surface of the substrate and perpendicular to the second direction; and
forming a third source/drain region and a fourth source/drain region on the second channel region.

10. The method of claim 9, further comprising:
forming a dielectric layer over the first gate region, wherein the first gate region and the second gate region are vertically separated by a portion of the dielectric layer.

11. The method of claim 9, wherein the first gate region partially wrapping around a portion of the first channel region beneath a top portion of the first channel region.

12. The method of claim 9, wherein the first gate region completely wraps around a portion of the first channel region beneath a top portion of the first channel region.

13. The method of claim 9, wherein forming the first transistor further comprises forming a first gate dielectric between the first channel region and the first gate region, and wherein the first gate dielectric comprises a vertical portion vertically extending in the first direction and arranged laterally between the first channel region and the first gate region, and a lateral portion arranged beneath the first gate region.

14. The method of claim 9, wherein forming the second transistor further comprises forming a second gate dielectric extending laterally in the third direction and arranged vertically between the second channel region and the second gate region.

15. The method of claim 9, further comprising:
forming a second conductive line on opposing sides of the first channel region and laterally extending in the second direction, wherein the first gate region of the first transistor is part of the second conductive line.

16. The method of claim 9, further comprising:
forming a third conductive line arranged above and electrically coupled to the third source/drain region of the second transistor, and
forming a fourth conductive line arranged above and electrically coupled to the fourth source/drain region of the second transistor.

17. A method of manufacturing an integrated chip, comprising:
forming a first conductive line over an upper surface of a substrate;
depositing a first channel layer over the first conductive line;
patterning the first channel layer to form a first channel region of a first transistor vertically extending in a first direction perpendicular to the upper surface of the substrate;
forming a first gate structure of the first transistor along the first channel region, and comprising a first gate region and a first gate dielectric, wherein the first transistor comprises a first source/drain region and a second source/drain region;
forming a second gate structure of a second transistor laterally extending in a second direction in parallel with the upper surface of the substrate, and comprising a second gate region directly over a top portion of the first channel region and a second gate dielectric region directly over the second gate region;
depositing a second channel region of the second transistor extending laterally in a third direction in parallel with the upper surface of the substrate and perpendicular to the second direction and directly over the second gate structure; and
forming a third source/drain region and at least a fourth source/drain region of the second transistor on the second channel region.

18. The method of claim 17, wherein forming the first gate structure comprises:
forming the first gate dielectric comprising a vertical portion along the first channel region and a lateral portion arranged over the first conductive line; and
forming the first gate region laterally separated from the first channel region by the vertical portion of the first gate dielectric and over the lateral portion of the first gate dielectric.

19. The method of claim 17, wherein patterning the first channel layer comprises:
forming a mask layer with patterns on the channel layer; and
etching the channel layer to form the first channel region.

20. The method of claim 17, wherein forming the first gate structure of the first transistor comprises:
depositing a first gate dielectric over the first conductive line and along sidewalls of the first channel region;
depositing a gate metal material on the first gate dielectric; and
etching the first gate dielectric and the gate metal material to form the first gate structure.
